(19) United States
(12) Patent Application Publication
(10) Pub. No.: US 2015/0259779 A1
(43) Pub. Date: Sep. 17, 2015

(54) MASK AND MANUFACTURING METHOD THEREFOR

(71) Applicants: BOE TECHNOLOGY GROUP CO., LTD., Beijing (CN); Ordos Yuansheng Optoelectronics Co., Ltd., Inner Mongolia (CN)

(72) Inventors: Qun Ma, Beijing (CN); Yutai Yuan, Beijing (CN); Minhui Jia, Beijing (CN)

(21) Appl. No.: 14/315,706

(22) Filed: Jun. 26, 2014

(30) Foreign Application Priority Data
Mar. 12, 2014 (CN) 201410090890.X

(51) Int. Cl. C23C 14/04

(52) U.S. Cl. CPC C23C 14/042

(57) ABSTRACT

An embodiment of the present invention discloses a mask. The mask comprises: a first surface; a second surface opposite to the first surface; at least one opening structure disposed onto the mask, wherein a pattern of the opening structure on the first surface partly overlaps with a pattern of the opening structure on the second surface in a direction perpendicular to the first surface or the second surface, wherein the overlapping area is a through hole. Furthermore, another embodiment of the present invention also discloses a method for manufacturing such mask.

### CROSS-REFERENCE TO RELATED APPLICATION

This application claims the benefit of Chinese Patent Application No. 201410090890.X filed on Mar. 12, 2014 in the State Intellectual Property Office of China, the whole disclosure of which is incorporated herein by reference.

### BACKGROUND OF THE INVENTION

1. Field of the Invention

The present disclosure relates to a technical field of display, more particularly, relates to a mask and a manufacturing method therefor.

2. Description of the Related Art

During manufacturing a display device, many manufacturing processes need to use masks, thereby forming a pattern comprised of specific structures onto a substrate. These specific structures can include grid lines, data lines, organic light emitting layers or the like.

Evaporation is one of the most important manufacturing processes. In the evaporation process, openings are disposed on the mask, corresponding to the specific structures, so as to form the specific structures during the evaporation. Specifically, a process of performing the evaporation onto the mask is as follows: overlaying the mask onto the substrate; inverting the substrate overlaid with the mask above an evaporating source, wherein substances emitted from the evaporating source pass through the openings of the mask and arrive at a surface of the substrate, so that a pattern including the specific structures is formed on the substrate. Therefore, sizes of the openings of the mask determine sizes of the formed specific structures.

Due to limitations from the manufacturing process of the masks, the openings onto the mask have relatively large sizes, so that the formed specific structures have larger sizes, which is not beneficial to improve an opening ratio and a resolution of the display device.

### SUMMARY OF THE INVENTION

In order to eliminate the above or other technical problems in the prior art, the present disclosure provides a mask and a manufacturing method therefor, so that the formed specific structures onto such mask have relatively small sizes.

In accordance with one aspect of the present invention, a mask is provided, comprising:

a first surface;

a second surface opposite to the first surface;

at least one opening structure disposed onto the mask, wherein a pattern of the opening structure on the first surface partly overlaps with a pattern of the opening structure on the second surface in a direction perpendicular to the first surface or the second surface, wherein the overlapping area is a through hole.

In accordance with another aspect of the present invention, a manufacturing method for a mask is provided, comprising the steps of:

forming at least one opening structure on the mask comprising two opposite first and second surfaces, wherein a pattern of the opening structure on the first surface partly overlaps with a pattern of the opening structure on the second surface in a direction perpendicular to the first surface or the second surface, and the overlapping area is a through hole.

### BRIEF DESCRIPTION OF THE DRAWINGS

The above and other features of the present invention will become more apparent by describing in detail exemplary embodiments thereof with reference to the accompanying drawings, in which:

FIG. 1 is a schematic sectional view of a mask in accordance with a first example of the present invention along a direction perpendicular to a first surface of the mask;

FIG. 2 is a top view of the mask as shown in FIG. 1;

FIG. 3 is a bottom view of the mask as shown in FIG. 1;

FIG. 4 is a schematic sectional view of a mask in accordance with a second example of the present invention along a direction perpendicular to a first surface of the mask;

FIG. 5 is a schematic sectional view of a mask in accordance with a third example of the present invention along a direction perpendicular to a first surface of the mask;

FIG. 6 is a schematic sectional view of a mask in accordance with a fourth example of the present invention along a direction perpendicular to a first surface of the mask;

FIG. 7 is a schematic sectional view of a mask in accordance with a fifth example of the present invention along a direction perpendicular to a first surface of the mask;

FIG. 8 is a schematic view of the mask after a first etching during the manufacturing process of the mask as shown in FIG. 1;

FIG. 9 is a schematic view of the mask after a second etching during the manufacturing process of the mask as shown in FIG. 8;

FIG. 10 is a flow chart of the manufacturing method of the mask as shown in FIG. 6.

### EXPLANATIONS OF REFERENCE NUMBERS

1—mask
2—opening structure;
3—frame
11—first sub-mask
12—second sub-mask
21—parttem of the opening structure on the first surface
22—pattern of the pending structure on the second surface
23—through hole
101—first surface of the mask
102—second surface of the mask;
111—first opening
121—second opening

### DETAILED DESCRIPTION OF PREFERRED EMBODIMENTS OF THE INVENTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### First Embodiment

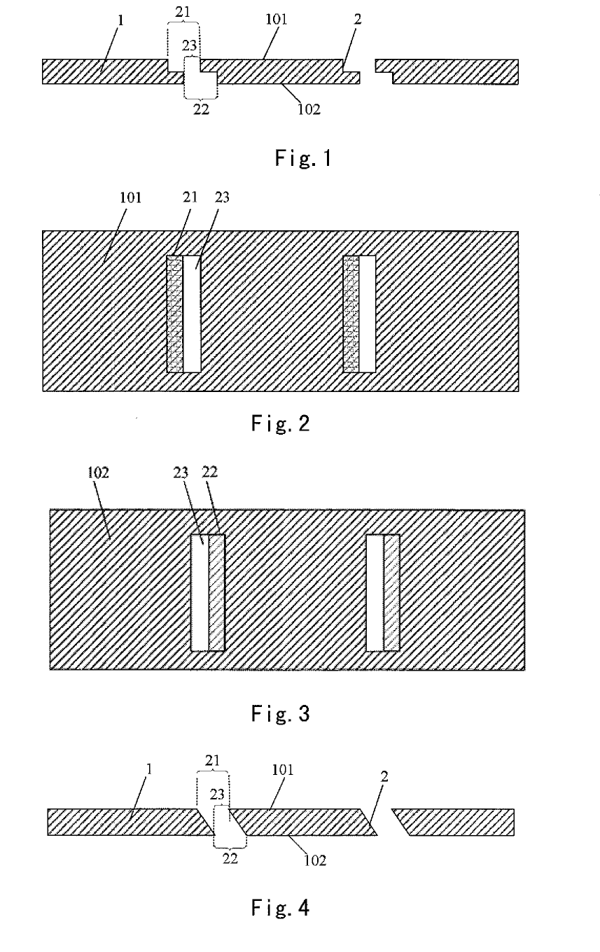

It can be seen from FIGS. 1-5 that the first embodiment of the present invention provides three different examples of masks, i.e., the first to third examples.

The first embodiment of the present invention provides a mask 1, on which the specific structures having relatively small sizes may be formed.

FIGS. 1-3 illustrate the mask 1 of the first example. The mask 1 includes a first surface 101 and a second surface 102 opposite to the first surface 101. At least one opening structure 2 (herein two opening structures are shown) is arranged onto the mask 1. A pattern 21 of the opening structure 2 on the first surface 101 partly overlaps with a pattern 22 of the opening structure 2 on the second surface 102, wherein the overlapping area is a through hole 23. When the mask 1 is used for deposition, the through hole 23 allows passage of substances to be deposited. When the mask 1 is used for exposure, the through hole 23 allows passage of light rays.

It should be noted that in one illustrative example of the present invention, as shown in FIG. 1, a non-overlapping area of the pattern 21 of the opening structure 2 on the first surface 101 with the pattern 22 of the opening structure 2 on the second surface 102 has a rectangular section along a direction perpendicular to the first surface 101 or the second surface 102.

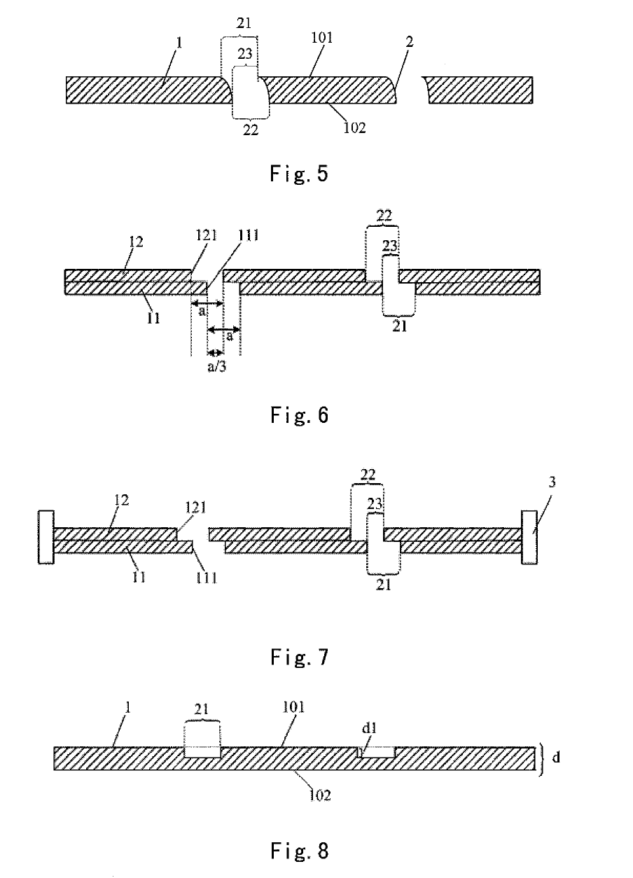

However, the section of the non-overlapping area along the direction perpendicular to the first surface 101 or the second surface 102 can also have many other shapes, for example, a triangle shape of the second example as shown in FIG. 4; a non-regular shape of the third example as shown in FIG. 5. It should be appreciated that other regular or non-regular shaped sections are also possible, and the embodiments of the present invention do not make any limitation thereto. Meanwhile, the opening structure 2 of the same shape can be manufactured by many methods, and the embodiments of the present invention do not make any limitation thereto either.

Further, in the first embodiment of the present invention, the mask 1 is made of stainless steel.

One embodiment of the present invention provides a mask. The mask includes first and second surfaces opposite to each other, and at least one opening structure is arranged onto the mask. A pattern of the opening structure on the first surface of the mask partly overlaps with a pattern of the opening structure on the second surface of the mask in a direction perpendicular to the first or the second surface, and the overlapping area is a through hole. Therefore, the size of the overlapping area must be less than the size of the patterns of the opening structures on the first and second surfaces. Furthermore, the specific structures to be formed by deposition or exposure have relative small sizes, thereby facilitating to improve an opening ratio and a resolution of the display device.

### Second Embodiment

The second embodiment of the present invention illustrates two further different examples of the mask 1, i.e., the example 4 and the example 5.

The example 4 of the present invention provides a mask 1 as shown in FIG. 6.

Specifically, the mask 1 includes a first sub-mask 11 and a second sub-mask 12 attached to each other. A surface of the first sub-mask 11 which is opposite to another surface of the first sub-mask 11 attached to the second sub-mask 12 is the first surface; whereas a surface of the second sub-mask 12 which is opposite to another surface of the second sub-mask 12 attached to the first sub-mask 11 is the second surface. A first opening 111 is provided onto the first sub-mask 11, and a pattern of the first opening 111 on the first surface is the pattern 21 of the opening structure 2 on the first surface; whereas a second opening 121 is provided onto the second sub-mask 12, and a pattern of the second opening 121 on the second surface is the pattern 22 of the opening structure 2 on the second surface. The pattern of the first opening 111 on the first surface 101 partly overlaps with the pattern of the second opening 121 on the second surface 102 in the direction perpendicular to the first surface 101 or the second surface 102, thereby forming the overlapping area or the through hole 23 which allows passage of the substances to be deposited or the light rays.

In one example, the first sub-mask 11 has the same size as that of the second sub-mask 12, and the first opening 111 has the same size as that of the second opening 121. Optionally, sections of the first opening 111 and the second opening 121 along the direction perpendicular to the first surface are rectangular shaped.

As shown in FIG. 6, sections of the first opening 111 and the second opening 121 along the direction perpendicular to the first surface 101 have a width of a respectively, and a section of the overlapping area 23 formed by the first opening 111 and the second opening 121 along the direction perpendicular to the first surface 101 has a width of a/3. Therefore, the size of the overlapping area 23 is much less than those of the first opening 111 or the second opening 121, which is helpful to form a pattern including more fine specific structures, on the substrate.

It should be noted that the mask 1 in the second embodiment of the present invention includes the first sub-mask 11 and the second sub-mask 12 attached to each other, but it is not limited to this. Illustratively, the mask 1 can include a plurality of sub-masks attached to each other, while a combination of the sizes and positions of the openings on the different sub-masks is also not limited to the case as described above. It should be appreciated that in the second embodiment of the present invention, one mask made of two sub-masks is taken as an example to explain the inventive concept and design principle of the present invention, but the person skilled in the art can select the number of the sub-masks for forming the mask as desired.

Further, as shown in FIG. 7, the mask further includes a frame 3, which is used to fix the first sub-mask 11 and the second sub-mask 12. Illustratively, the first sub-mask 11 is firstly fixed onto the frame 3, and the second sub-mask 12 is then fixed onto the frame 3, so as to attach it to the first sub-mask.

In an illustrative example, when the first opening 111 on the first sub-mask 11 is identical or entirely corresponds with the second opening 121 in terms of positions and sizes, during the fixing process it is necessary for the second sub-mask 12 to be set with a certain displacement or a predetermined distance from the first sub-mask 11, so that the first opening 111 overlaps with the second opening 121, thus forming the overlapping area 23.

In another illustrative example, when the first opening 111 of the first sub-mask 11 has the same size as that of the second opening 121 of the second sub-mask 12, but the first opening 111 is displaced from the second opening 121 or the first opening 111 is set from the second opening 121 at a certain predetermined distance; during the fixing process, it is necessary to fully or directly attach the second sub-mask 12 to the first sub-mask 11, so that the first opening 111 partly overlaps with the second opening 121, thus forming the overlapping area 23. In the second embodiment of the present invention, the frame 3 is made of metal. Therefore, the first sub-mask 11 and the second sub-mask 12 can be fixed to the frame 3 by means of welding.

With reference to the accompanying drawings, the manufacturing methods for the masks provided by the first and second embodiments of the present invention are explained below.

An embodiment of the present invention provides a method for manufacturing the mask. The method includes the following steps:

at least one opening structure 2 is formed onto the mask 1 including two opposite first and second surfaces 101 and 102. The pattern 21 of the opening structure 2 on the first surface 101 partly overlaps with the pattern 22 of the opening structure 2 on the second surface 102, and the overlapping area is the through hole 23.

The mask 1 provided by the first embodiment is a single piece, i.e., the mask 1 is single. When the mask 1 is manufactured in the first embodiment, the step of forming the opening structure onto the mask including two opposite first and second surfaces, includes the following two processes:

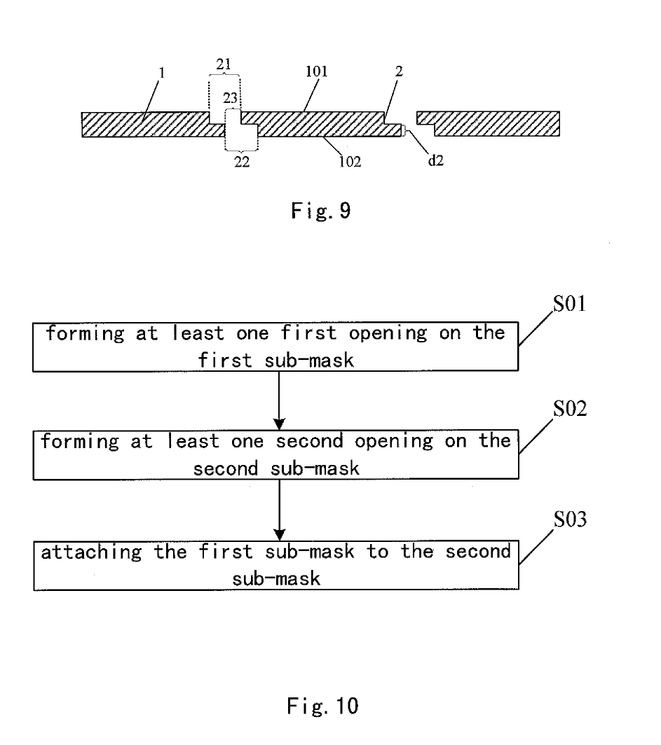

Process I: the mask 1 as shown in FIG. 1 is completed by at least two etchings. Firstly, the first surface 101 of the mask 1 having a thickness of d is etched, to form the pattern 21 of the opening structures 2 on the first surface 101 with an etching depth of d1, wherein d1<d. After the first etching, the mask 1 has the structure as shown in FIG. 8. Secondly, the second surface of the mask 1 is etched, to form the pattern 22 of the opening structures 2 on the second surface 102 with an etching depth of d2, wherein d−d1≦d2<d. After the second etching, the mask 1 has the structure as shown in FIG. 9. The pattern 21 of the opening structure 2 on the first surface 101 partly overlaps with the pattern 22 of the opening structure 2 on the second surface 102 in the direction perpendicular to the first surface 101 or the second surface 102. During the etching process of the first and second surfaces 101 and 102, they both etch the overlapping area 23. Therefore, the overall etching depth at the overlapping area 23 is d1+d2, i.e., a sum of d1 and d2. It can be known from the above description that d1+d2>d. Therefore, the metal at the overlapping area 23 is entirely etched away, so that the substance to be deposited or the light rays can pass through it. It should be appreciated that the opening structure 2 can be formed onto the mask 1 by more than twice etchings. That is, each opening structure 2 is not limited to have two openings in the direction perpendicular to the first surface 101, as shown in FIGS. 1-3. Each opening structure 2 includes at least two openings in the direction perpendicular to the first surface 101 or the second surface 102, which partly overlap with each other in the direction perpendicular to the first surface or the second surface, thereby forming the through hole extending from the first surface to the second surface throughout the opening structure.

In FIGS. 1-3, the opening structure each including a first opening arranged onto the first surface 101 and a second opening arranged onto the second surface 102 adjacent to the first opening, is taken as one example for explanation and interpretation. The first and second openings within the opening structure 2 partly overlap with each other in the direction perpendicular to the first surface 101 or the second surface 102, so as to form the through hole 23 for communicating the first opening to the second opening.

Process II: a dry etching method can be used to manufacture the mask 1 as shown in FIG. 4. During such etching process, a plasma beam is set at a certain angle with respect to the mask 1.

As shown in FIG. 10, when manufacturing the mask 1 as described in the second embodiment, the method of forming the opening structures onto the mask including two opposite first and second surfaces specifically includes the following steps:

Step S01, forming at least first opening onto the first sub-mask.

Herein, two manufacturing methods are typically used to form the first openings 111 onto the first sub-mask 11.

Method 1: the first openings 111 are directly formed onto the first sub-mask 11 by an etching method.

Method 2: firstly, first predetermined openings are formed onto the first sub-mask 11, and have the same position and shape as those of the first openings 111, but the first predetermined openings have sizes less than the first openings 111. Secondly, since the first sub-mask 11 has a relatively less thickness, the material thereof is soft such that wrinkles will tend to occur. Thus, after forming the first predetermined openings onto the first sub-mask 11, it is necessary to prestress the first sub-mask 11, so that there is no wrinkle on the first sub-mask 11. Finally, the first sub-mask 11 is stretched so that the first predetermined openings are deformed, thereby forming the first openings 111.

S02: forming at least second opening onto the second sub-mask.

Similar to the step S01, it is also possible to select two manufacturing methods to form the second openings 121 onto the second sub-mask 12.

The method 1′: the second openings 121 are directly formed onto the second sub-mask 12 by the etching method.

The method 2′: firstly, second predetermined openings are formed onto the second sub-mask 12, and have the same position and shape as those of the second opening 121, but the second predetermined openings have sizes less than the second openings 121. Secondly, since the second sub-mask 12 has a relatively less thickness, the material thereof is soft such that wrinkles will tend to occur. Thus, after forming the second predetermined openings onto the second sub-mask 12, it is necessary to prestress the second sub-mask 12, so that there is no wrinkle on the second sub-mask 12. Finally, the second sub-mask 12 is stretched so that the second predetermined openings are deformed, thereby forming the second openings 121.

S03: attaching the first sub-mask to the second sub-mask.

Specifically, the attaching process of the first and second sub-masks can include the following several cases:

Case I: when each first opening 111 on the first sub-mask 11 has the same position and sizes as those of the second opening 121 on the second sub-mask 12 (for example, the first sub-mask with the first openings is identical with the second sub-mask with the second openings; or such first sub-mask 11 is in mirror symmetry with such second sub-mask), each first opening 111 overlaps with each second opening 121 by means of attaching the first and second sub-masks 11 and 12 with displacement, thus forming the overlapping areas 23.

Case II: when only the first opening 111 on the first sub-mask 11 has the same size as that of the second opening 121 on the second sub-mask 12, but they are displaced from each other, the first opening 111 partly overlaps with the second opening 121 by entirely attaching the first and second sub-masks 11 and 12, thus forming the overlapping area 23.

Moreover, the attaching process of the first sub-mask 11 and the second sub-mask 12 of the mask 1 includes the above described cases I and II, but is not limited to this. The repeated description will be omitted in embodiments of the present invention.

After attaching the first sub-mask 11 to the second sub-mask 12, a surface of the first sub-mask 11 which is opposite to a surface of the first sub-mask 11 attached to the second sub-mask 12 is the first surface 101; whereas a surface of the second sub-mask 12 which is opposite to a surface of the second sub-mask 12 attached to the first sub-mask 11, is the second surface 102. A pattern of the first opening 111 on the first surface 101 is the pattern 21 of the opening structure 2 on the first surface 101; whereas a pattern of the second opening 121 on the second surface 102 is the pattern 22 of the opening structure 2 on the second surface 102.

During the above described manufacturing process of mask 1, the formed first opening 11 and second opening 12 can have a relatively larger size, avoiding the problem that the openings having relatively small sizes cannot be manufactured onto the mask 1 in the prior art. Then, the overlapping area 23 having relatively small size can be formed by partly overlapping of the first opening 11 with the second opening 12, so that the present mask 1 can be used to form specific structure having small sizes on the substrate.

Further, with respect to the manufacturing method of the mask 1 including the frame 3 as shown in FIG. 7, the step S03 of attaching the first and second sub-masks 11 and 12 further includes the steps:

the first and second sub-masks 11 and 12 are fixed to the same frame 3 to attach them together.

The specific procedures are as follows:

Firstly, the first metal sub-mask 11 is stretched by a stretcher, to test quality of the first metal sub-mask 11 and the first openings 111.

Secondly, a force is applied to the frame 3 to compress it. The first sub-mask 11 is stretched, and welded to the frame 3 in a compressed state.

Again, the force applied onto the frame 3 is removed, and due to restoration of the frame 3, a pulling force is exerted onto the first sub-mask 11, so that it is stretched and thus the first predetermined openings become the first openings 111.

After that, the same steps are used to fix the second sub-mask 12 onto the frame 3, so that the second sub-mask 12 is located above the first sub-mask 11, thus forming the mask 1 as shown in FIG. 7.

The embodiment of the present invention provides a method for manufacturing the mask. The method includes: forming opening structures onto the mask including two opposite first and second surfaces. The pattern of the opening structure on the first surface partly overlaps with the pattern of the opening structure on the second surface in the direction perpendicular to the first surface or the second surface, and the overlapping area is the through hole. Therefore, the size of the overlapping area is certainly less than that of the pattern of the opening structure on the first surface or the second surface, so that the size of the specific structure formed by deposition or exposure is relatively small, thus facilitating to improve the opening ratio and the resolution of the display device.

Although several exemplary embodiments have been shown and described, the present invention is not limited to those and it would be appreciated by those skilled in the art that various changes or modifications may be made in these embodiments without departing from the principles and spirit of the disclosure. These changes or modifications also fall within the scope of the present invention. The scope of the present invention is defined by the claims and their equivalents.

What is claimed is:

1. A mask comprising:
a first surface;
a second surface opposite to the first surface;
at least one opening structure disposed onto the mask, wherein a pattern of the opening structure on the first surface partly overlaps with a pattern of the opening structure on the second surface in a direction perpendicular to the first surface or the second surface, wherein the overlapping area is a through hole.

2. The mask according to claim 1, wherein the mask comprises at least two sub-masks attached to each other, and unattached surfaces of two outermost sub-masks of the at least two sub-masks are the first surface and the second surface, respectively.

3. The mask according to claim 1, wherein the mask comprises a first sub-mask and a second sub-mask attached to each other,
a surface of the first sub-mask which is opposite to another surface of the first sub-mask attached to the second sub-mask is the first surface; wherein a surface of the second sub-mask which is opposite to another surface of the second sub-mask attached to the first sub-mask is the second surface,
at least one first opening is provided onto the first sub-mask, and a pattern of the first opening on the first surface is the pattern of the opening structure on the first surface;
wherein at least one second opening is provided onto the second sub-mask, and a pattern of the second opening on the second surface is the pattern of the opening structure on the second surface.

4. The mask according to claim 3, wherein the first sub-mask has the same size as that of the second sub-mask, and each of the at least one first opening has the same size as that of each of the at least one second opening.

5. The mask according to claim 4, wherein sections of the first opening and the second opening along the direction perpendicular to the first surface or the second surface are rectangular shaped.

6. The mask according to claim 5, wherein the sections of the first opening and the second opening along the direction perpendicular to the first surface have a width of a respectively, and a section of the overlapping area formed by the first opening and the second opening along the direction perpendicular to the first surface has a width of a/3.

7. The mask according to claim 2, wherein it further comprises a frame configured to fix the at least two sub-masks.

8. The mask according to claim 1, wherein a non-overlapping area of the pattern of the opening structure on the first surface with the pattern of the opening structure on the second surface has a rectangular section, a triangular section, or other regular or non-regular shaped sections along the direction perpendicular to the first surface or the second surface.

9. The mask according to claim 1, wherein the mask is a single piece, and each of the at least one opening structure comprises at least two openings in the direction perpendicular to the first surface or the second surface, which partly overlap with each other in the direction perpendicular to the first surface or the second surface, for forming the through hole extending from the first surface to the second surface throughout the opening structure.

10. The mask according to claim 9, wherein each of the at least one opening structure comprises a first opening arranged onto the first surface and a second opening arranged onto the second surface adjacent to the first opening, wherein the first opening and the second opening within the same opening structure partly overlap with each other in the direction perpendicular to the first surface or the second surface, so as to form the through hole for communicating the first opening with the second opening.

11. The mask according to claim 10, wherein each of the at least one first opening and each of the at least one second opening have a rectangular section along the direction perpendicular to the first surface or the second surface;
the sections of the first opening and the second opening along the direction perpendicular to the first surface have a width of a respectively, a section of the overlapping area formed by the first opening and the second opening along the direction perpendicular to the first surface has a width of a/3.

12. A method for manufacturing a mask, comprising the steps of:
forming at least one opening structure on the mask comprising two opposite first and second surfaces, wherein a pattern of the opening structure on the first surface partly overlaps with a pattern of the opening structure on the second surface in a direction perpendicular to the first surface or the second surface, and the overlapping area is a through hole.

13. The method according to claim 12, wherein the step of forming the at least one opening structure on the mask comprising two opposite first and second surfaces comprises:
etching the first surface of the mask, to form the pattern of the opening structure on the first surface with an etching depth of d1, wherein d1<d, d being a thickness of the mask;
etching the second surface of the mask, to form the pattern of the opening structure on the second surface with an etching depth of d2, wherein d−d1≦d2<d; or
forming the opening structure on the mask comprising the opposite first and second surfaces by a dry etching method.

14. The method according to claim 12, wherein the step of forming the at least one opening structure on the mask comprising two opposite first and second surface comprises:
forming at least one opening on at least two sub-masks respectively;
attaching the at least two sub-masks to each other.

15. The method of claim 14, wherein the step of forming the at least one opening structure on the mask comprising two opposite first and second surfaces comprises:
forming at least one first opening on the first sub-mask;
forming at least one second opening on the second sub-mask;
attaching the first sub-mask to the second sub-mask;
wherein a surface of the first sub-mask which is opposite to another surface of the first sub-mask attached to the second sub-mask is the first surface; wherein a surface of the second sub-mask which is opposite to another surface of the second sub-mask attached to the first sub-mask is the second surface,
wherein a pattern of the first opening on the first surface is the pattern of the opening structure on the first surface; wherein a pattern of the second opening on the second surface is the pattern of the opening structure on the second surface.

16. The method according to claim 15, wherein the step of attaching the first sub-mask to the second sub-mask comprises:
fixing the first sub-mask and the second sub-mask onto the same frame, to attach them together.

17. The method according to claim 15, wherein the step of attaching the first and second sub-masks comprises:
attaching the first and second sub-masks by displacement, when the first opening on the first sub-mask has the position and size entirely corresponding to those of the second opening on the second sub-mask, so that the first opening of the first sub-mask partly overlaps with the second opening of the second sub-mask adjacent to the first opening, in the direction perpendicular to the first surface or the second surface; or
directly attaching the first and second sub-masks to each other, when the first opening on the first sub-mask has the same size as that of the second opening on the second sub-mask, but the first opening on the first sub-mask does not correspond to the second opening on the second sub-mask in term of their positions, so that the first opening of the first sub-mask partly overlaps with the second opening of the second sub-mask adjacent to the first opening in the direction perpendicular to the first surface or the second surface.

18. The method according to claim 15, wherein
the step of forming at least one first opening on the first sub-mask comprises:
forming at least one first predetermined opening on the first sub-mask, wherein the first predetermined opening has the same position and shape as those of the first opening to be manufactured but has a size less than that of the first opening,
prestressing the first sub-mask,
stretching the first sub-mask to form the first opening;
the step of forming at least one second opening on the second sub-mask comprises:
forming at least one second predetermined opening on the second sub-mask, wherein the second predetermined opening has the same position and shape as those of the second opening to be manufactured but has a size less than that of the second opening,
prestressing the second sub-mask,
stretching the second sub-mask to form the second opening.

19. The method according to claim 18, wherein
the step of fixing the first and second sub-masks with the frame comprises:
applying a force to the frame to make it in a compressed state;
stretching the first and second sub-masks and welding them to the frame in the compressed state;
removing the force applied on the frame, and exerting a pulling force onto the first and second sub-masks by restoration of the frame, so that the first and second predetermined openings become the first and second openings respectively.

20. The method according to claim 15, wherein
the step of forming at least one first opening on the first sub-mask comprises:
directly forming the first opening on the first sub-mask by an etching method;
the step of forming at least one second opening on the second sub-mask comprises:
directly forming the second opening on the second sub-mask by an etching method.
